(19) United States
(12) Patent Application Publication
(10) Pub. No.: US 2022/0077184 A1
(43) Pub. Date: Mar. 10, 2022

(54) SEMICONDUCTOR DEVICE AND MANUFACTURING METHOD THEREOF

(71) Applicant: Kioxia Corporation, Tokyo (JP)

(72) Inventors: Atsushi FUKUMOTO, Kuwana (JP); Junya FUJITA, Nagoya (JP); Osamu ARISUMI, Kuwana (JP); Fan WEN, Yokkaichi (JP); Takayuki ITO, Yokkaichi (JP)

(73) Assignee: Kioxia Corporation, Tokyo (JP)

(21) Appl. No.: 17/304,260

(22) Filed: Jun. 17, 2021

(30) Foreign Application Priority Data
Sep. 9, 2020 (JP) 2020-151455

(51) Int. Cl. H01L 27/11582; H01L 21/225

(52) U.S. Cl. CPC H01L 27/11582; H01L 21/2255

(57) ABSTRACT

A semiconductor device according to one embodiment includes a substrate, a wiring layer provided on the substrate and including source lines, a stacked body including a plurality of conductive layers and a plurality of insulating layers alternately stacked on the wiring layer, a cell film provided in the stacked body, a semiconductor film facing the cell film in the stacked body, and a diffusion film being in contact with the source lines in the wiring layer and being in contact with the semiconductor film in the stacked body. The diffusion film includes impurities and a top end portion of the diffusion film is at a higher position than a lowermost conductive layer among the conductive layers.

### CROSS-REFERENCE TO RELATED APPLICATIONS

This application is based upon and claims the benefit of priority from Japanese Patent Application No. 2020-151455, filed on Sep. 9, 2020; the entire contents of which are incorporated herein by reference.

### FIELD

Embodiments of the present invention relate to a semiconductor device and a manufacturing method thereof.

### BACKGROUND

A stacked body including a plurality of electrode layers, and a channel film penetrating through the stacked body are provided in a semiconductor device having a memory cell array of a three-dimensional structure. With regard to such a structure of the semiconductor device, a DSC (Direct Strap Contact) structure is known where a sidewall of the channel film is in direct contact with source lines provided below the stacked body. The channel film produces holes due to gate-induced drain leakage (GIDL). When sufficient holes are accumulated, data is erased.

In the semiconductor device having the DSC structure described above, the source lines are doped with impurities such as phosphorus (P). These impurities diffuse into the channel film at the time of occurrence of the GIDL described above.

### BRIEF DESCRIPTION OF THE DRAWINGS

FIG. 1 is a perspective view illustrating a structure of relevant parts of a semiconductor device according to a first embodiment;

FIG. 2 is a diagram illustrating a part of a cross section along a section line A-A illustrated in FIG. 1;

FIG. 3 is a sectional view illustrating a part of FIG. 2 in an enlarged manner;

FIG. 4A is a sectional view illustrating a process of stacking a circuit layer and a wiring layer on a substrate;

FIG. 4B is a sectional view illustrating a process of forming a stacked body on the wiring layer;

FIG. 4C is a sectional view illustrating a process of forming a hole;

FIG. 4D is a sectional view illustrating a process of forming a cell film in holes;

FIG. 4E is a sectional view illustrating a process of forming a diffusion film;

FIG. 4F is a sectional view illustrating a process of etching a part of the diffusion film;

FIG. 4G is a sectional view illustrating a process of forming a semiconductor film;

FIG. 4H is a sectional view illustrating a process of forming a slit;

FIG. 4I is a sectional view illustrating a process of selectively etching insulating layers;

FIG. 4J is a sectional view illustrating a process of forming a conductive layer and a source line;

FIG. 4K is a sectional view illustrating a process of embedding an insulating film in holes and slits;

FIG. 5 is a sectional view of relevant parts of a semiconductor device according to a second embodiment;

FIG. 6A is a sectional view illustrating a process of forming a semiconductor film on an inner side of a cell film;

FIG. 6B is a sectional view illustrating a process of forming a first core insulating film on an inner side of the semiconductor film;

FIG. 6C is a sectional view illustrating a process of etching a part of the first core insulating film;

FIG. 6D is a sectional view illustrating a process of annealing the first core insulating film; and

FIG. 6E is a sectional view illustrating a process of embedding a second core insulating film in holes.

### DETAILED DESCRIPTION

Embodiments will now be explained with reference to the accompanying drawings. The present invention is not limited to the embodiments.

A semiconductor device having a memory cell array of a three-dimensional structure is described in the following embodiments. This semiconductor device is a NAND non-volatile semiconductor storage device that can electrically and freely perform erase and write of data and that can retain storage contents even when power is off.

A semiconductor device according to one embodiment includes a substrate, a wiring layer provided on the substrate and including source lines, a stacked body including a plurality of conductive layers and a plurality of insulating layers alternately stacked on the wiring layer, a cell film provided in the stacked body, a semiconductor film facing the cell film in the stacked body, and a diffusion film being in contact with the source lines in the wiring layer and being in contact with the semiconductor film in the stacked body. The diffusion film includes impurities and a top end portion of the diffusion film is at a higher position than a lowermost conductive layer among the conductive layers.

### First Embodiment

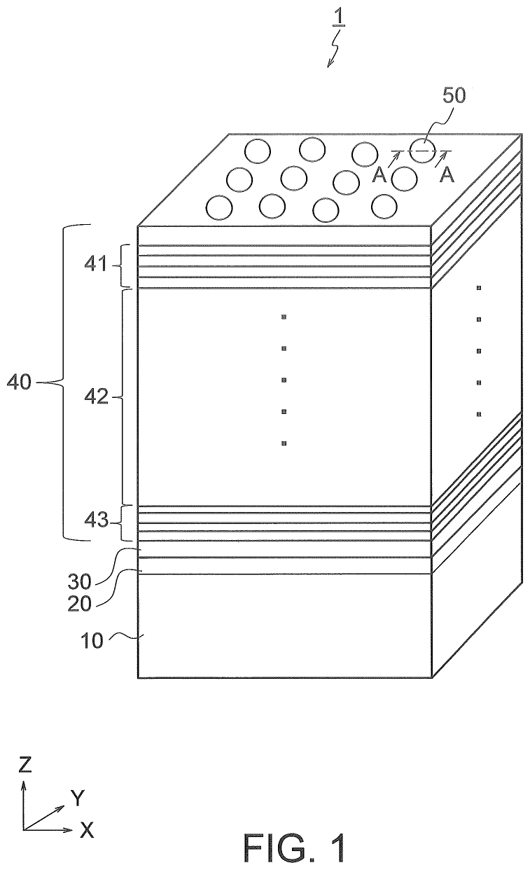

FIG. 1 is a perspective view illustrating a structure of relevant parts of a semiconductor device according to a first embodiment. A semiconductor device 1 illustrated in FIG. 1 includes a substrate 10, a circuit layer 20, a wiring layer 30, a stacked body 40, and a plurality of columnar parts 50. In the following explanations, two directions parallel to the substrate 10 and orthogonal to each other are an X direction and a Y direction. A direction perpendicular to the substrate 10 and orthogonal to the X direction and the Y direction is a Z direction. The Z direction is also the stacking direction of the stacked body 40.

The substrate 10 is, for example, a silicon substrate. The circuit layer 20 is provided on the substrate 10. The circuit layer 20 includes peripheral circuits for memory cells provided in the columnar parts 50. Transistors and the like used to drive the memory cells are arranged as the peripheral circuits. The wiring layer 30 is provided on the circuit layer 20. The wiring layer 30 includes source lines electrically connected to the columnar parts 50. The stacked body 40 is provided on the wiring layer 30.

The stacked body 40 includes an SGD 41, a cell 42, and an SGS 43. The SGD 41 is located in an upper layer part of the stacked body 40 and includes a plurality of drain-side selection gate electrodes. The SGS 43 is located in a lower layer part of the stacked body 40 and includes a plurality of source-side selection gate electrodes. The cell 42 is located between the SGD 41 and SGS 43 and includes a plurality of word lines.

The columnar parts 50 are arranged in a staggered manner in the X direction and the Y direction. The columnar parts 50 extend in the Z direction in the wiring layer 30 and the stacked body 40.

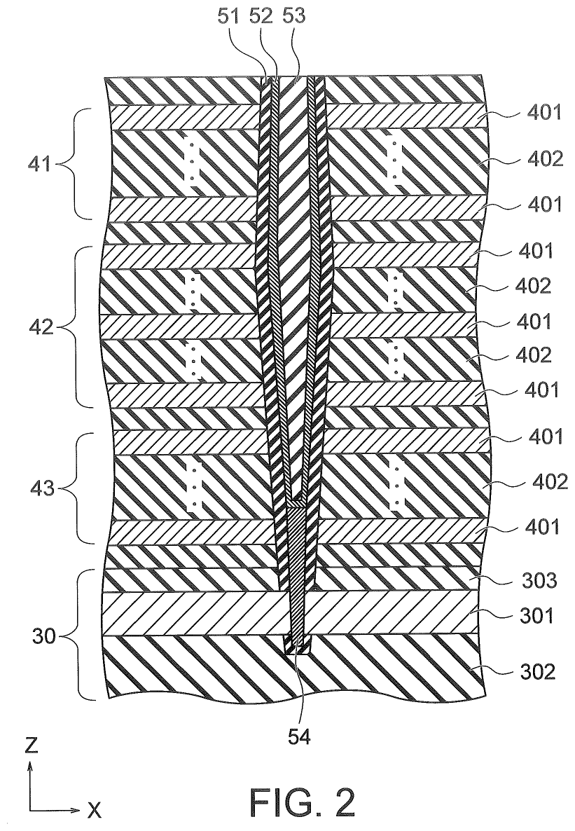

FIG. 2 is a diagram illustrating a part of a cross section along a section line A-A illustrated in FIG. 1. Structures of the wiring layer 30, the stacked body 40, and the columnar parts 50 are explained below with reference to FIG. 2.

The structure of the wiring layer 30 is explained first. Source lines 301 are formed in the wiring layer 30 between an insulating layer 302 and an insulating layer 303. The source lines 301 are, for example, metal such as tungsten (W), polycrystalline silicon, or amorphous silicon doped with impurities such as phosphorus. The insulating layer 302 and the insulating layer 303 include, for example, silicon dioxide (SiO₂).

The structure of the stacked body 40 is explained next. As illustrated in FIG. 2, a plurality of conductive layers 401 and a plurality of insulating layers 402 in a flat plate form are alternately stacked in the Z direction in the stacked body 40. Each of the conductive layers 401 includes a metal film including tungsten or the like and a barrier metal film including titanium nitride (TiN) or the like. The barrier metal films are formed between the metal films and the insulating layers 402. Meanwhile, the insulating layers 402 include silicon dioxide. The conductive layers 401 are insulated and isolated by the insulating layers 402.

Conductive layers 401 formed in the SGD 41 among the conductive layers 401 are the drain-side selection gate electrodes described above. Conductive layers 401 formed in the cell 42 are the word lines described above. Conductive layers 401 formed in the SGS 43 are the source-side selection gate electrodes described above.

The structure of the columnar parts 50 is explained next. The columnar part 50 illustrated in FIG. 2 includes a cell film 51, a semiconductor film 52, a core insulating film 53, and a diffusion film 54. The cell film 51, the semiconductor film 52, and the core insulating film 53 are formed in the stacked body 40. The diffusion film 54 is formed in the wiring layer 30 and the stacked body 40.

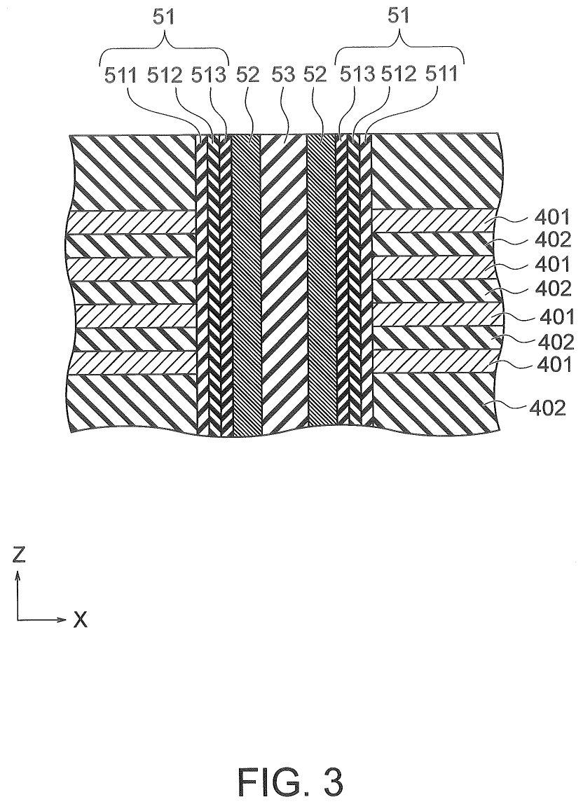

FIG. 3 is a sectional view illustrating a part of FIG. 2 in an enlarged manner. As illustrated in FIG. 3, the cell film 51 is a stacked film including a block dielectric film 511, a charge accumulating film 512, and a tunnel dielectric film 513. The block dielectric film 511 and the tunnel dielectric film 513 include, for example, silicon dioxide. The charge accumulating film 512 includes, for example, silicon nitride (SiN). A high-dielectric constant insulating film (High-k) material may be used as materials of the block dielectric film 511, the charge accumulating film 512, and the tunnel dielectric film 513.

In the semiconductor device 1 according to the present embodiment, intersections between the cell film 51 and the conductive layers 401 are vertical transistors. Among the vertical transistors, intersections between the conductive layers 401 (the drain-side selection gate electrodes) in the SDG 41 and the cell film 51 are drain-side selection transistors. Intersections between the conductive layers 401 (the source-side selection gate electrodes) in the SGS 43 and the cell film 51 are source-side selection transistors. Intersections between the conductive layers 401 (the word lines) in the cell 42 and the cell film 51 are memory cells. The drain-side selection transistors, the memory cells, and the source-side selection transistors are connected in series.

The semiconductor film 52 faces the tunnel dielectric film 513. The semiconductor film 52 includes non-doped amorphous silicon having a lower phosphorus concentration than that in the diffusion film 54. The semiconductor film 52 is a channel film that produces holes due to GIDL. The GIDL occurs when opposite voltages are respectively applied to a drain and a gate. When sufficient holes are accumulated, charges accumulated in the charge accumulating film 512, that is, data is erased.

The core insulating film 53 faces the semiconductor film 52. The core insulating film 53 includes, for example, silicon dioxide.

Referring back to FIG. 2, the diffusion film 54 is in contact with the source lines 301 and is also in contact with the semiconductor film 52. In the diffusion film 54, phosphorus (P) is included as impurities in amorphous silicon. The diffusion film 54 is protruded into the SGS 43. That is, the top end portion of the diffusion film 54 is at a higher position than a lowermost conductive layer 401. The diffusion film 54 may include impurities causing the conductivity type of silicon to be an n⁻ type or a p⁻ type instead of impurities, such as phosphorus, causing the conductivity type to be an n+ type.

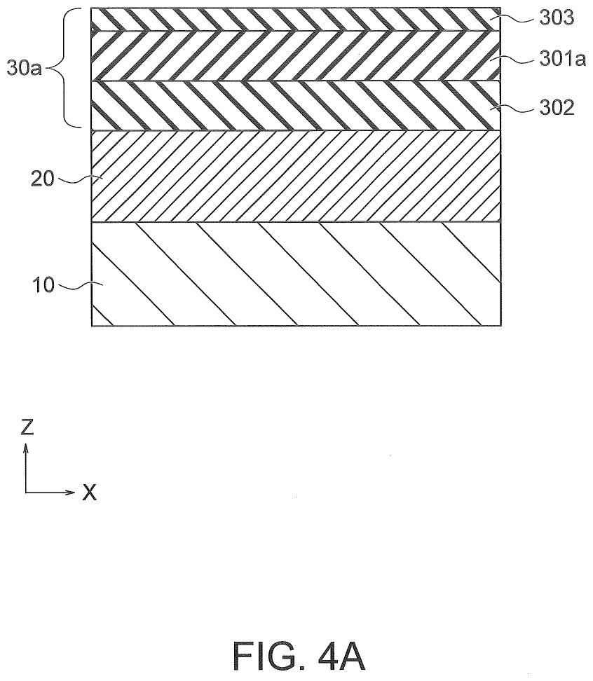

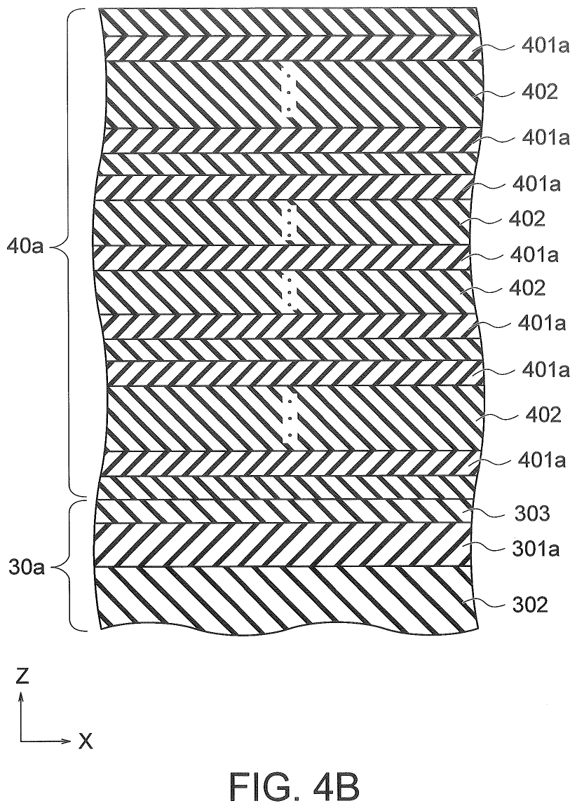

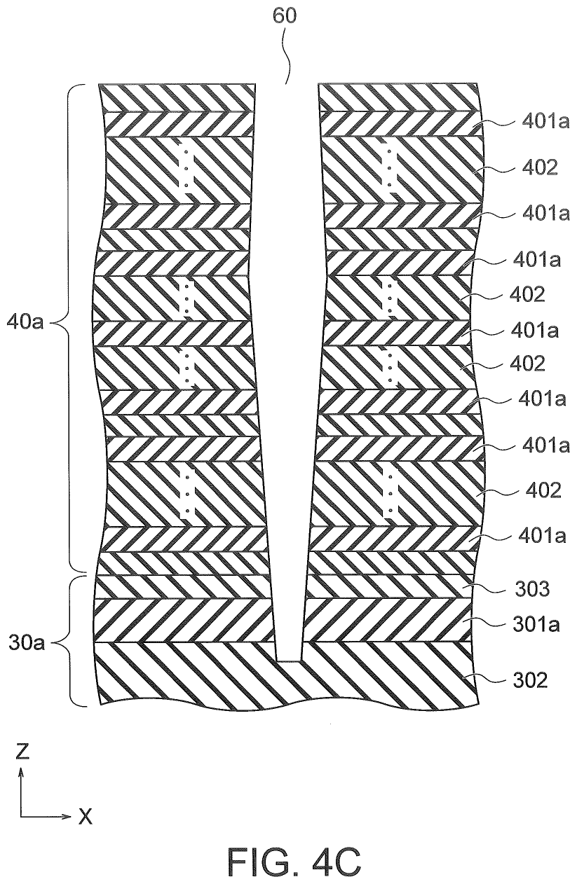

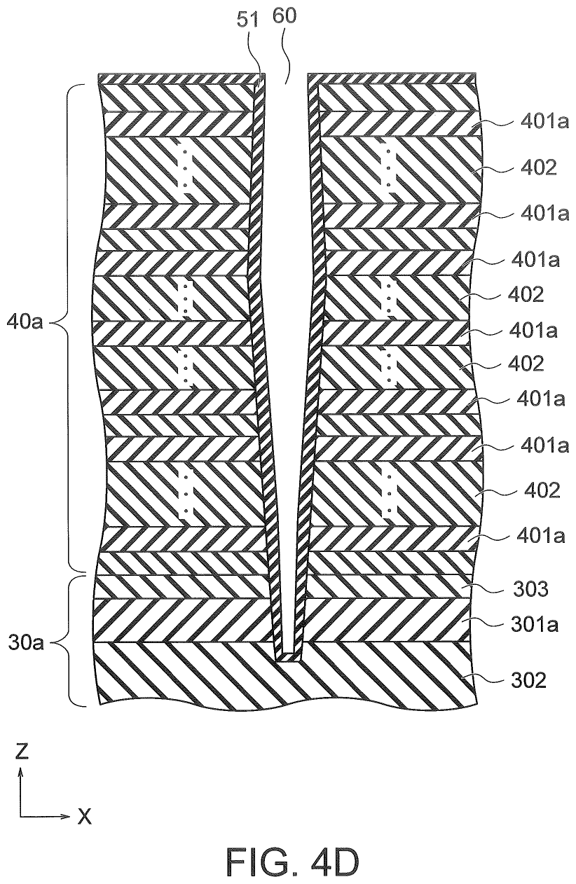

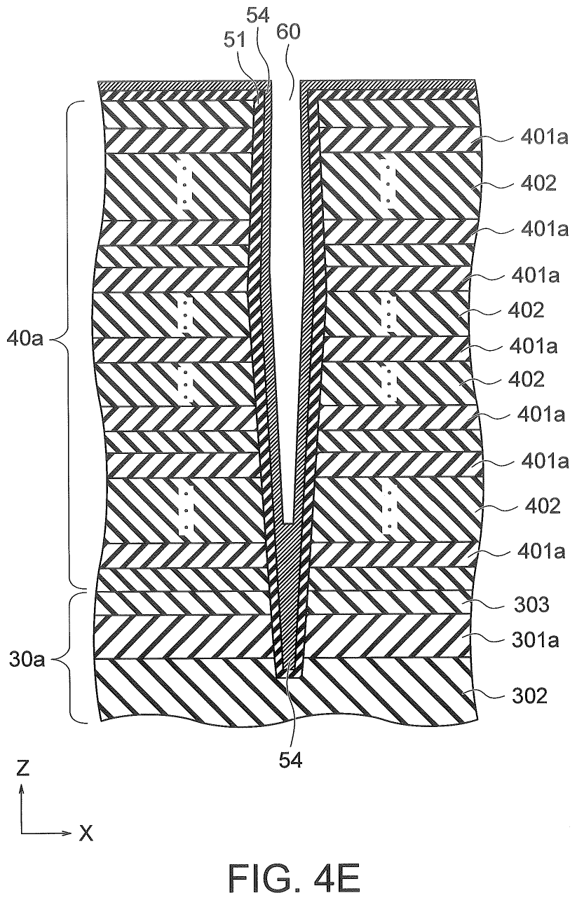

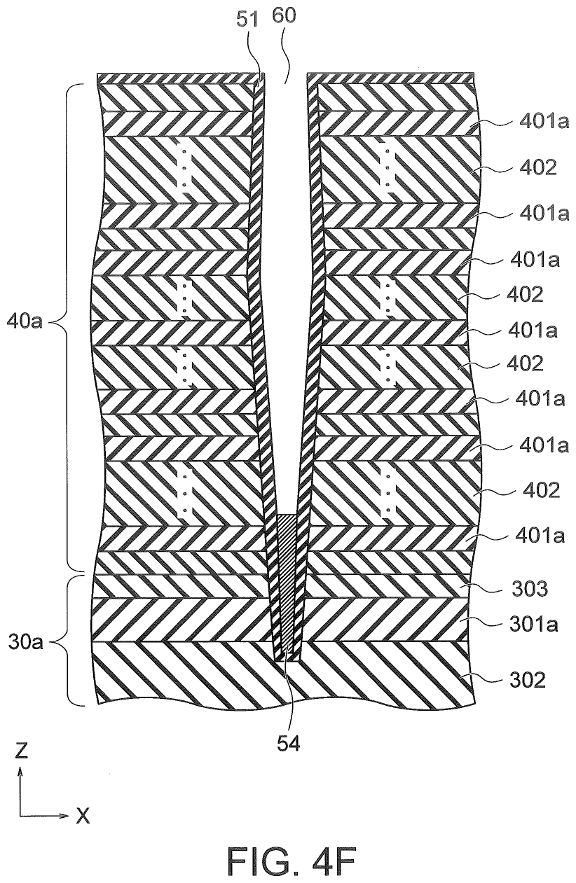

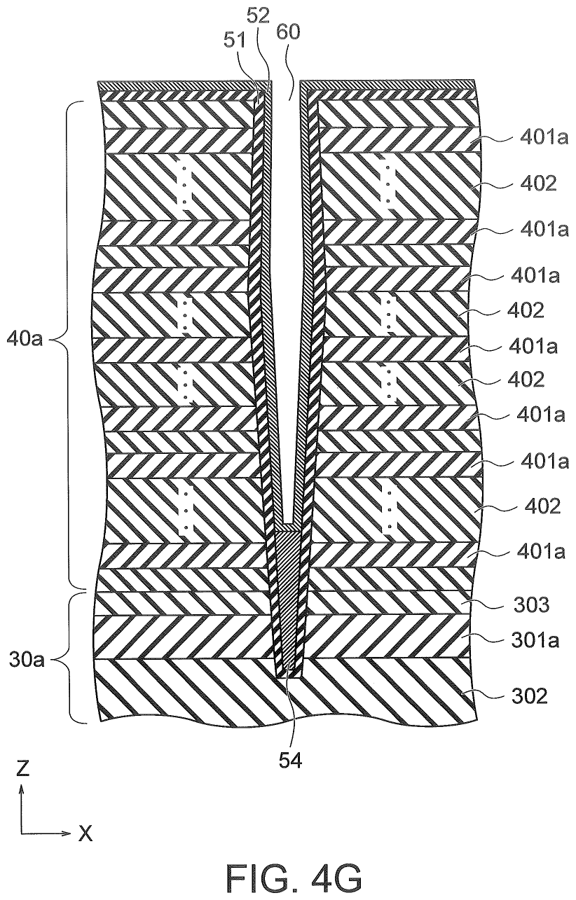

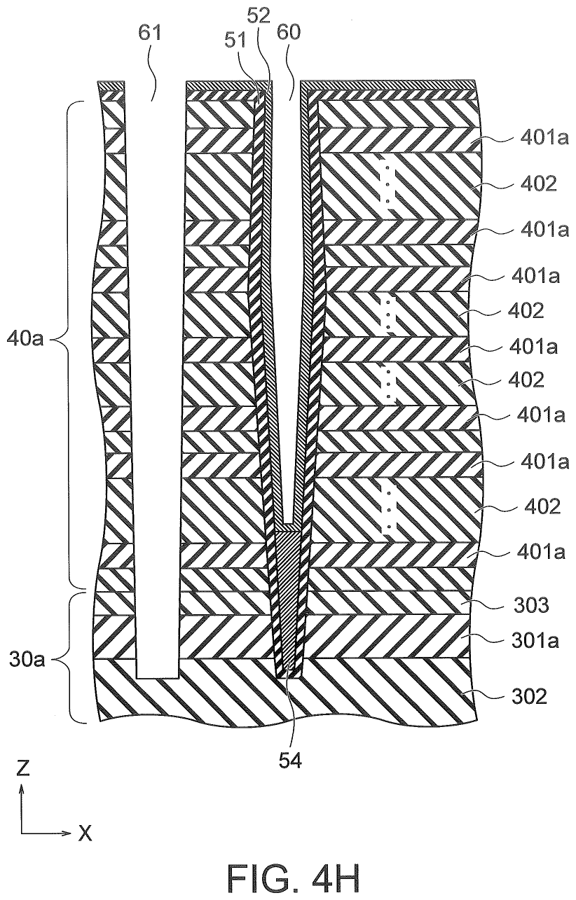

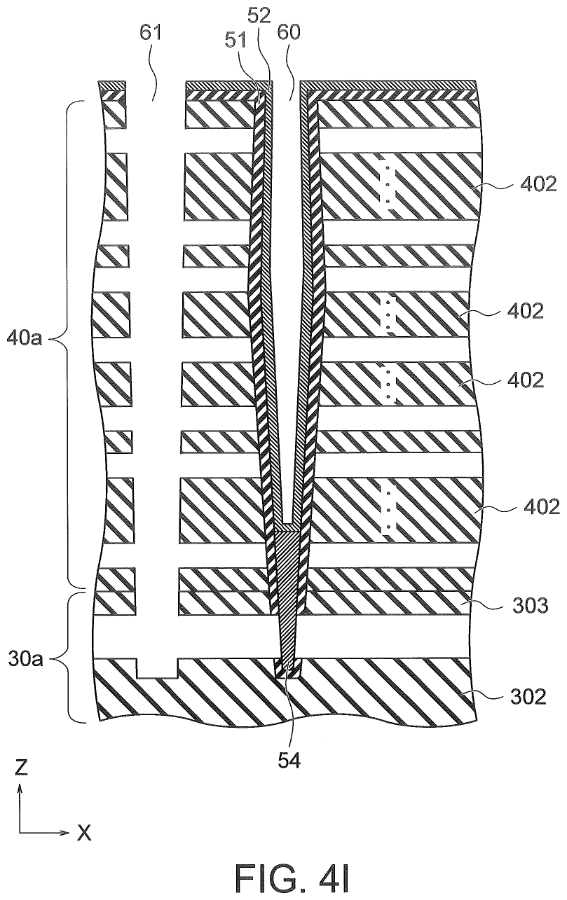

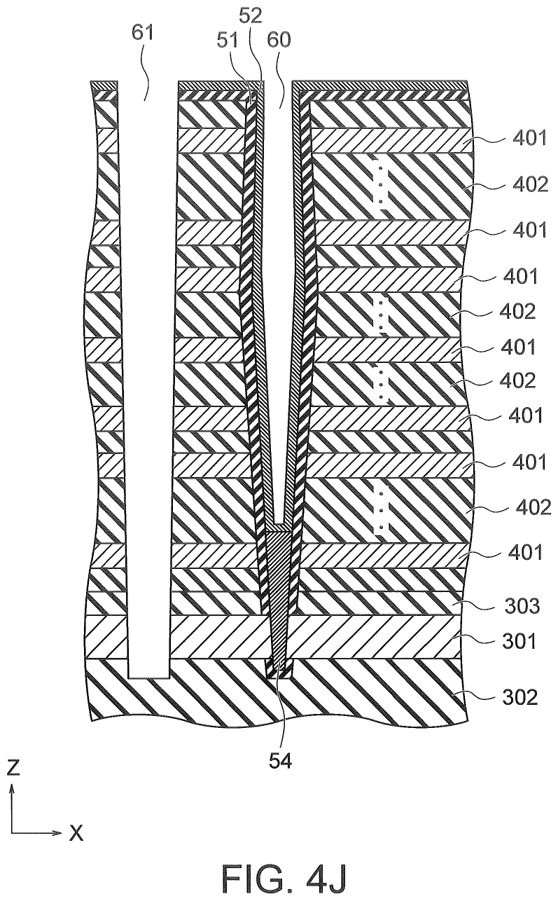

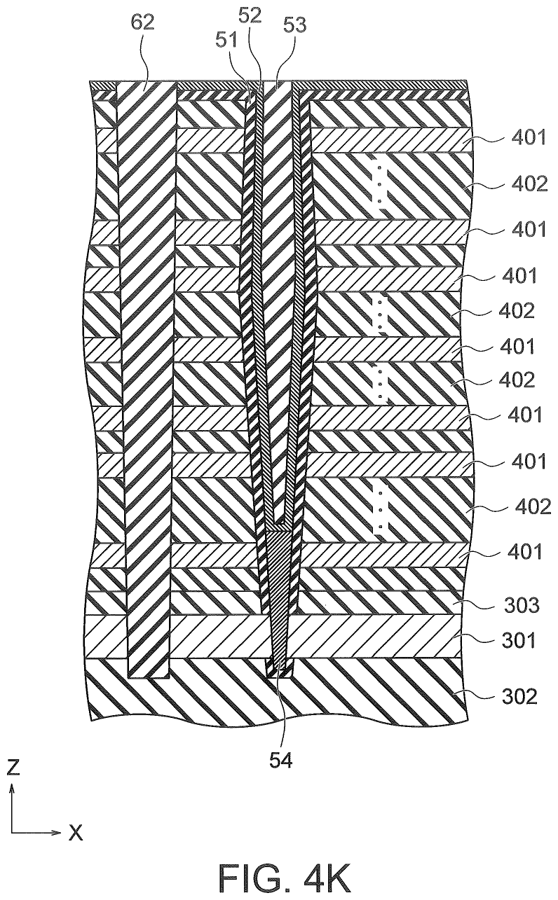

A manufacturing process of the semiconductor device according to the present embodiment is explained below with reference to FIGS. 4A to 4K.

First, as illustrated in FIG. 4A, the circuit layer 20 and a wiring layer 30a are successively stacked on the substrate 10. Since the circuit layer 20 and the wiring layer 30a can be formed by a method generally used, detailed explanations thereof are omitted. In the wiring layer 30a, an insulating film 301a is formed between the insulating layer 302 and the insulating layer 303. This insulating film 301a is an example of a first insulating film including silicon nitride and is replaced with the source line 301 in a process described later.

Next, a stacked body 40a is formed on the wiring layer 30a as illustrated in FIG. 4B. The stacked body 40a can be formed, for example, by CVD (Chemical Vapor Deposition) or ALD (Atomic Layer Deposition). In the stacked body 40a, a plurality of insulating layers 401a and the insulating layers 402 are alternately stacked in the Z direction. The insulating layers 402 are an example of second insulating layers and include, for example, silicon dioxide. The insulating layers 401a are an example of first insulating layers including silicon nitride and are replaced with the conductive layers 401 in a process described later.

Next, holes 60 are formed, for example, by RIE (Reactive Ion Etching) at arrangement places of the columnar parts 50 as illustrated in FIG. 4C. The holes 60 penetrate in the Z direction through the stacked body 40a and the insulating layers 303 and the insulating film 301a in the wiring layer 30 to end in the insulating layer 302.

Next, the cell film 51 is formed in the holes 60 as illustrated in FIG. 4D. Specifically, the block dielectric film 511, the charge accumulating film 512, and the tunnel dielectric film 513 illustrated in FIG. 3 are formed continuously in this order.

Next, as illustrated in FIG. 4E, the diffusion film 54 is formed on an inner side of the cell film 51, for example, by CVD. The diffusion film 54 is formed using amorphous silicon doped with phosphorus. Since bottom portions of the holes 60 are narrow at that time, the bottom portions are filled with the diffusion film 54.

Next, a part of the diffusion film 54 is etched conformally as illustrated in FIG. 4F. As a result, parts of the diffusion film 54 embedded in the bottom portions of the holes 60 remain and other parts are removed. Etching of the diffusion film 54 may be dry etching such as CDE (Chemical Dry Etching) or wet etching.

In the case of dry etching, the diffusion film 54 can be etched, for example, by introducing a mixture gas including nitrogen trifluoride (NF₃) and oxygen (O₂) under a condition of a pressure of 107 Pa (800 mtorr). In the case of wet etching, the diffusion film 54 can be etched, for example, by using trimethyl-2 hydroxyethyl ammonium hydroxide (TMY) as a chemical.

Etching of the diffusion film 54 can be isotropic etching or anisotropic etching. Particularly in the case of anisotropic etching, the amount of etching of the diffusion film 54, in other words, the height of the diffusion film 54 remaining in the bottom portions of the holes 60 can be controlled. In the present embodiment, the top end portion of the diffusion film 54 is controlled to be at a higher position than a lowermost insulating layer 401a in the stacked body 40a.

Next, the semiconductor film 52 is formed on an inner side of the cell film 51 and on the diffusion film 54 as illustrated in FIG. 4G. The semiconductor film 52 is, for example, a non-doped amorphous silicon film formed by CVD.

Subsequently, several processes are performed to form slits 61, for example, by RIE as illustrated in FIG. 4H. The slits 61 also penetrate in the Z direction through the stacked body 40a and the insulating layer 303 and the insulating film 301a in the wiring layer 30 to end in the insulating layer 302 similarly to the holes 60.

Next, the insulating layers 401a and the insulating films 301a are selectively etched using the slits 61 as illustrated in FIG. 41. For example, a phosphoric acid solution is used as a chemical in this etching. Parts of the cell film 51 in contact with the insulating film 301a are removed in this etching. As a result, the diffusion film 54 is exposed.

Next, as illustrated in FIG. 43, the conductive layer 401 is formed at positions where the insulating layers 401a have been removed and the source line 301 is formed at positions where the insulating film 301a has been removed. Accordingly, the source lines 301 come in contact with the diffusion film 54 and therefore the source lines 301 are electrically connected to the semiconductor film 52 via the diffusion film 54.

Next, the core insulating film 53 is embedded in the holes 60 as illustrated in FIG. 4K. An insulating film 62 is embedded in the slits 61. The insulating film 62 includes, for example, silicon dioxide. Finally, unnecessary films remaining on the top surface of the stacked body 40 are removed. The semiconductor device 1 illustrated in FIG. 2 is thereby completed.

According to the present embodiment explained above, the diffusion film 54 including phosphorus is embedded in the bottom portions of the holes 60. This diffusion film 54 has a structure raised up to the SGS 43 in the stacked body 40. Therefore, at the time of occurrence of GIDL, the diffusion distance for phosphorus is ensured and variation in the diffusion distance is reduced. This stabilizes the phosphorus diffusion range and accordingly the data erase performance can be enhanced.

Further, formation of the diffusion film 54 eliminates the need for doping the source lines 301 with impurities such as phosphorus in the present embodiment. Therefore, the source lines 301 can be formed of metal. In this case, a situation where silicon seams remain in the source lines 301 can be avoided and the reliability of the device is accordingly improved.

### Second Embodiment

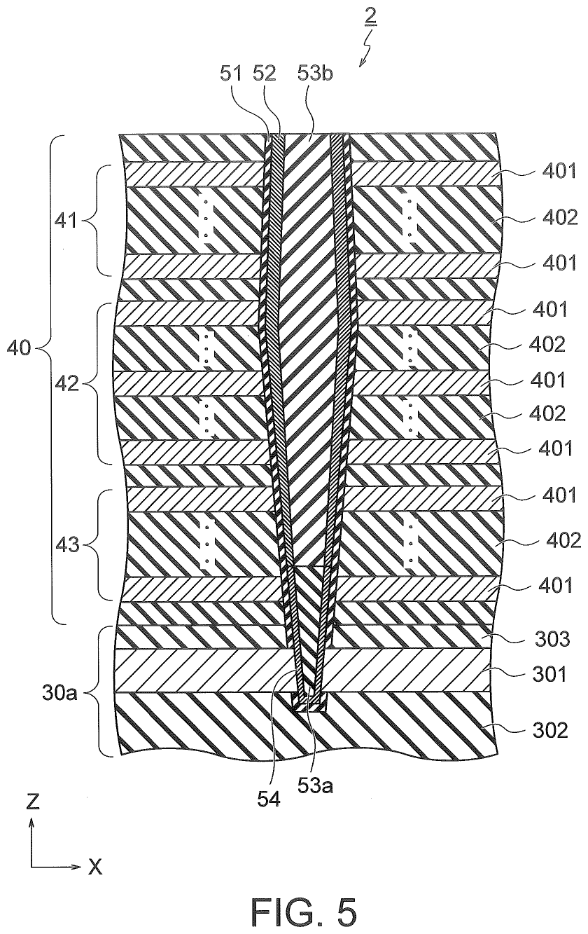

FIG. 5 is a sectional view of relevant parts of a semiconductor device according to a second embodiment. Constituent elements identical to those in the first embodiment are denoted by like reference characters and detailed explanations thereof are omitted.

A semiconductor device 2 illustrated in FIG. 5 is different from that in the first embodiment in including a first core insulating film 53a and a second core insulating film 53b. The first core insulating film 53a faces the diffusion film 54. The first core insulating film 53a includes the same concentration of phosphorus as that in the diffusion film 54 as impurities.

Meanwhile, the second core insulating film 53b faces the semiconductor film 52. The phosphorus concentration in the second core insulating film 53b is lower than that in the first core insulating film 53a.

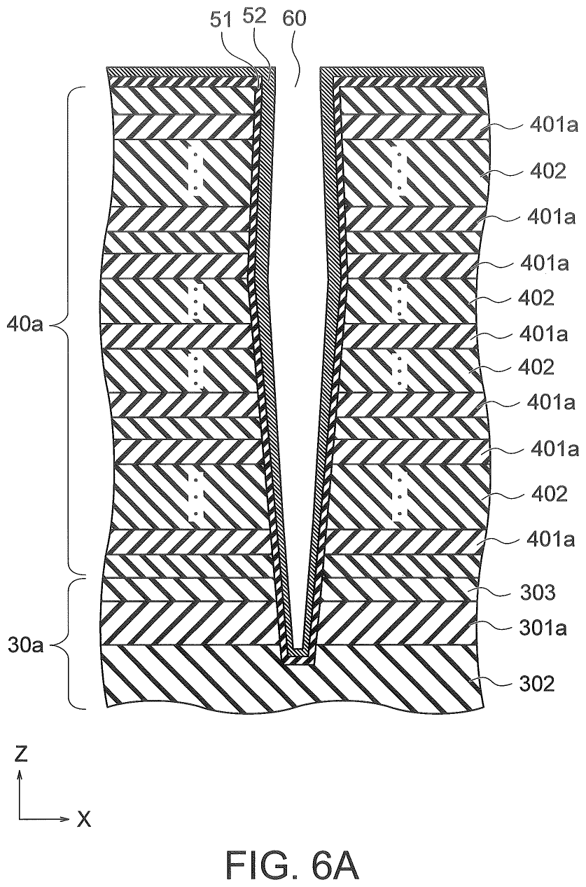

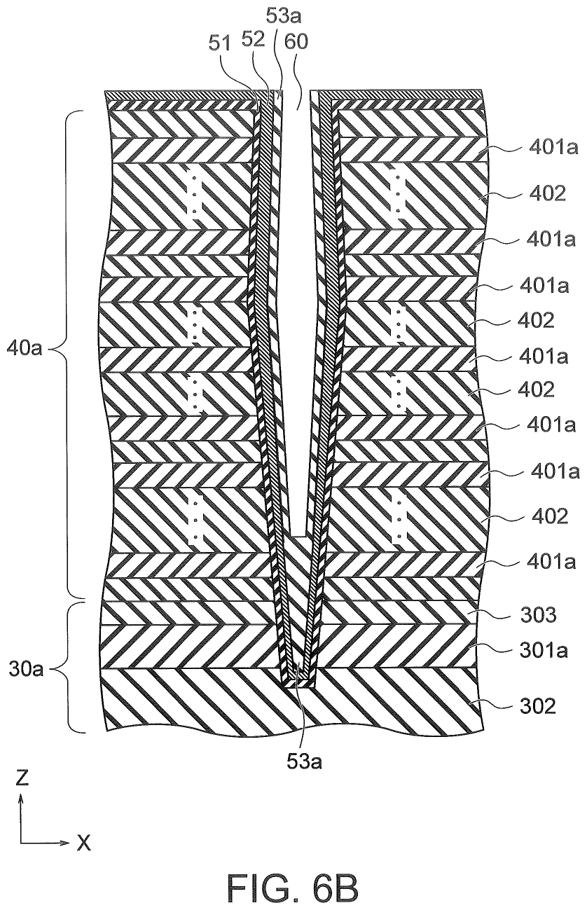

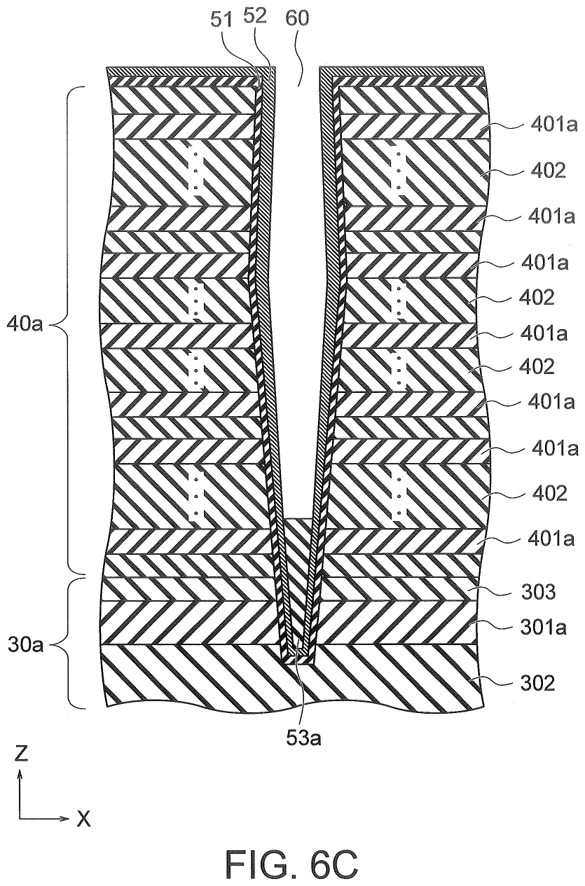

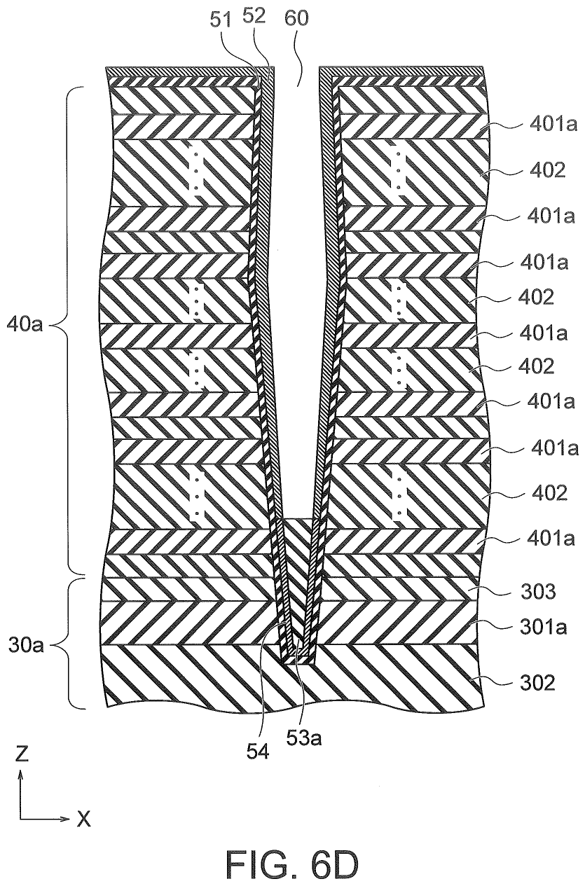

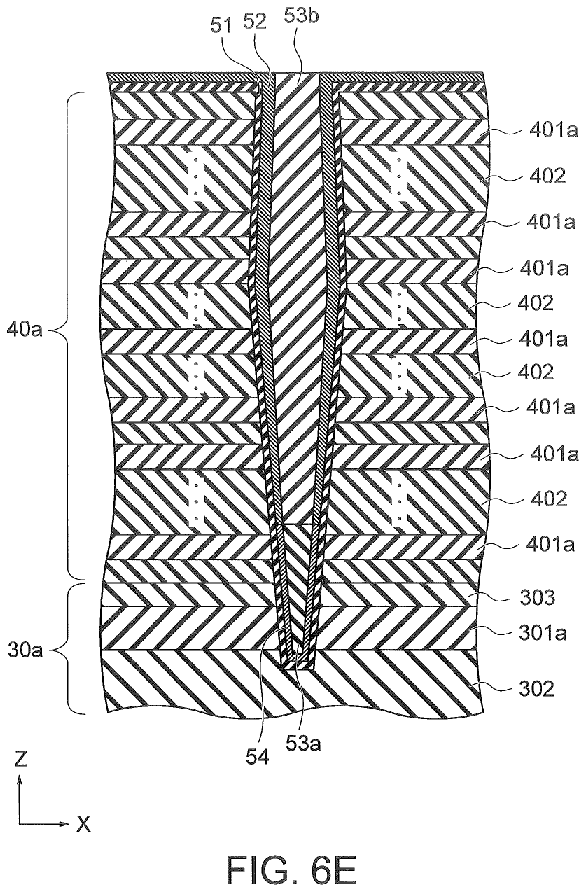

A manufacturing process of the semiconductor device according to the present embodiment is explained below with reference to FIGS. 6A to 6E. Since processes until the cell film 51 is formed in the holes 60 are same as those in the first embodiment, explanations thereof are omitted.

After the cell film 51 is formed, the semiconductor film 52 is formed on an inner side of the cell film 51, for example, by CVD as illustrated in FIG. 6A. The semiconductor film 52 is, for example, an amorphous silicon film.

Next, the first core insulating film 53a is formed on an inner side of the semiconductor film 52, for example, by ALD as illustrated in FIG. 6B. The first core insulating film 53a is formed using silicon dioxide doped with phosphorus. The bottom portions of the holes 60 are narrow at that time and therefore are filled with the first core insulating film 53a.

Next, as illustrated in FIG. 6C, the first core insulating film 53a is conformally etched. As a result, parts of the first core insulating film 53a embedded in the bottom portions of the holes 60 remain and other parts are removed.

Etching of the first core insulating film 53a can be dry etching such as CDE or wet etching. Further, the etching of the first core insulating film 53a can be isotropic etching or anisotropic etching. In the case of anisotropic etching, the amount of etching of the first core insulating film 53a, in other words, the height of the first core insulating film 53a remaining in the bottom portions of the holes 60 can be controlled. In the present embodiment, a top end portion of the first core insulating film 53a is controlled to be at a higher position than the lowermost insulating layer 401a in the stacked body 40a.

Next, the first core insulating film 53a is annealed, for example, under a condition of a temperature higher than 1000° C. Accordingly, a part of phosphorus included in the first core insulating film 53a diffuses into the semiconductor film 52. As a result, a part of the semiconductor film 52 facing the first core insulating film 53a changes to the diffusion film 54 including phosphorus as illustrated in FIG. 6D.

Next, the second core insulating film 53b is embedded in the holes 60 as illustrated in FIG. 6E. The second core insulating film 53b includes non-doped silicon dioxide having a lower phosphorus concentration than that in the first core insulating film 53a.

Subsequently, the slits 61 (see FIG. 4J) are formed, and the insulating layers 401a are replaced with the conductive layers 401 and the insulating film 301a is replaced with the source lines 301 using the slits 61, in the same manner as that in the first embodiment. The cell film 51 facing the insulating films 301a is etched to directly connect the source lines 301 to the diffusion film 54. The semiconductor device 2 illustrated in FIG. 5 is thereby completed.

According to the embodiment explained above, the first core insulating film 53a including phosphorus is embedded in advance in the bottom portions of the holes 60. With annealing of the first core insulating film 53a, phosphorus diffuses into the semiconductor film 52 to form the diffusion film 54. The diffusion film 54 also has a structure raised up to the SGS 43 in the stacked body 40 similarly to the first embodiment. Accordingly, at the time of occurrence of GIDL, the diffusion distance for phosphorus is ensured and variation in the diffusion distance is reduced. Since this stabilizes the phosphorus diffusion range, the data erase performance can be enhanced.

Also in the present embodiment, the diffusion film 54 in contact with the source lines 301 and the semiconductor film 52 is formed and accordingly the need for doping the source lines 301 with impurities such as phosphorus is eliminated. Therefore, with formation of the source lines 301 with metal, a situation where silicon seams remain can be avoided and the reliability of the device is improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a substrate;
a wiring layer provided on the substrate and including source lines;
a stacked body including a plurality of conductive layers and a plurality of insulating layers alternately stacked on the wiring layer;
a cell film provided in the stacked body;
a semiconductor film facing the cell film in the stacked body; and
a diffusion film being in contact with the source lines in the wiring layer and being in contact with the semiconductor film in the stacked body, wherein
the diffusion film includes impurities and a top end portion of the diffusion film is at a higher position than a lowermost conductive layer among the conductive layers.

2. The device of claim 1, wherein the source lines include metal.

3. The device of claim 1, wherein the semiconductor film is a channel film including non-doped silicon having a lower concentration of the impurities than that in the diffusion film.

4. The device of claim 1, further comprising:
a first core insulating film facing the diffusion film and including the impurities; and
a second core insulating film facing the semiconductor film on the first core insulating film and having a lower concentration of the impurities than that in the first core insulating film.

5. The device of claim 4, wherein a concentration of the impurities in the first core insulating film is equal to that of the impurities in the diffusion film.

6. A manufacturing method of a semiconductor device, the method comprising:
forming a wiring layer comprising a first insulating film on a substrate;
forming a stacked body including a plurality of first insulating layers and a plurality of second insulating layers alternately stacked on the wiring layer;
forming holes penetrating through the first insulating film and the stacked body;
forming a cell film in the holes;
embedding a diffusion film including impurities in bottom portions of the holes, the diffusion film having a top end portion at a higher position than a lowermost first insulating layer among the first insulating layers;
forming a semiconductor film facing the cell film on the diffusion film;
replacing the first insulating film with source lines being in contact with the diffusion film; and
replacing the first insulating layers with conductive layers.

7. The method of claim 6, wherein the source line is formed of metal.

8. The method of claim 6, wherein a channel film including non-doped silicon having a lower concentration of the impurities than that in the diffusion film is formed as the semiconductor film.

9. A manufacturing method of a semiconductor device, the method comprising:
forming a wiring layer including a first insulating film on a substrate;
forming a stacked body including a plurality of first insulating layers and a plurality of second insulating layers alternately stacked on the wiring layer;
forming holes penetrating through the first insulating film and the stacked body;
forming a cell film in the holes;
forming a semiconductor film facing the cell film in the holes;
embedding a first core insulating film including impurities in bottom portions of the holes, the first core insulating film having a top end portion at a higher position than a lowermost first insulating layer among the first insulating layers;
forming a diffusion film by diffusing the impurities from the first core insulating film into a part of the semiconductor film;
forming a second core insulating film facing the semiconductor film on the first core insulating film;
replacing the first insulating film with source lines being in contact with the diffusion film; and
replacing the first insulating layers with conductive layers.

10. The method of claim 9, wherein the source line is formed of metal.

11. The method of claim 9, wherein a channel film including non-doped silicon having a lower concentration of the impurities than that in the diffusion film is formed as the semiconductor film.

12. The method of claim 9, wherein a concentration of the impurities in the first core insulating film is equal to that of the impurities in the diffusion film.
